(19) United States
(12) Patent Application Publication
(10) Pub. No.: US 2016/0352324 A1
(43) Pub. Date: Dec. 1, 2016

(54) SWITCH CIRCUIT AND JBOD WITHIN THE SWITCH CIRCUIT

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: JIN-SHAN MA, Shenzhen (CN); MENG-LIANG YANG, Shenzhen (CN)

(21) Appl. No.: 14/795,320

(22) Filed: Jul. 9, 2015

(30) Foreign Application Priority Data
May 26, 2015 (CN) 201510273085.5

(51) Int. Cl. H03K 17/28; G06F 9/44; G06F 1/28; H03K 17/60

(52) U.S. Cl. CPC H03K 17/28; H03K 17/60; G06F 9/4405; G06F 1/28

(57) ABSTRACT

A switch circuit for a just a bunch of disks (JBOD) includes a selection module, a trigger module, a delay module, and a control module. The selection module is configured to receive a button signal. The trigger module is coupled to the selection module to receive a selection signal and output a power on trigger signal or a power off trigger signal. The delay module is configured to receive the button signal and output a delay signal after a preset time. The control module is coupled between the delay module and the selection module to receive the delay signal and then output a control signal to the selection module. The disclosure further provides a JBOD.

### FIELD

The subject matter herein generally relates to a switch circuit and a just a bunch of disks (JBOD) within the switch circuit.

### BACKGROUND

Traditional just a bunch of disks (JBOD) is switched by software, however software malfunctions may enable the JBOD to be normally switched.

### BRIEF DESCRIPTION OF THE DRAWINGS

Implementations of the present technology will now be described, by way of example only, with reference to the attached figures.

FIG. 1 is a block diagram of an example embodiment of a just a bunch of disks (JBOD), the JBOD comprising a switch circuit and a power supply unit, the switch circuit comprising a selection module, a trigger module, a delay module, and a control module.

FIG. 2 is a circuit diagram of an example embodiment of the selection module of FIG. 1.

FIG. 3 is a circuit diagram of an example embodiment of the trigger module of FIG. 1, the trigger module electrically coupled to the power supply unit.

FIG. 4 is a circuit diagram of an example embodiment of the delay module of FIG. 1.

FIG. 5 is a circuit diagram of an example embodiment of the control module of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a switch circuit 100.

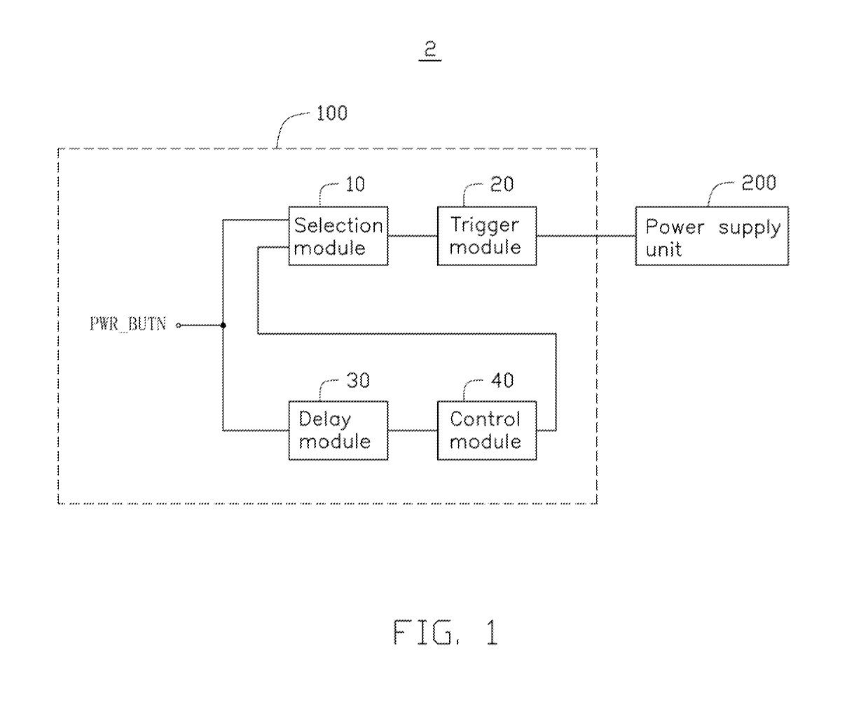

FIG. 1 illustrates an embodiment of the switch circuit 100 coupled to a power supply unit 200 of an electronic device. In at least one embodiment, the electronic device is a just bunch of disks (JBOD) 2. The switch circuit 100 can comprise a selection module 10, a trigger module 20, a delay module 30, and a control module 40. In at least one embodiment, the switch circuit 100 is positioned in the JBOD 2.

The selection module 10 is configured to receive a button signal PWR_BUTN. The selection module 10 is coupled to the control module 40 to receive a control signal. The selection module 10 is configured to output a selection signal to the trigger module 20 according to the control signal. The trigger module 20 is configured to output a trigger signal to the power supply unit 200 according to the selection signal. The delay module 30 is configured to receive the button signal and then output a delay signal to the control module 40 after a preset time. The control module 40 is configured to output the control signal to the selection module 10 according to the delay signal.

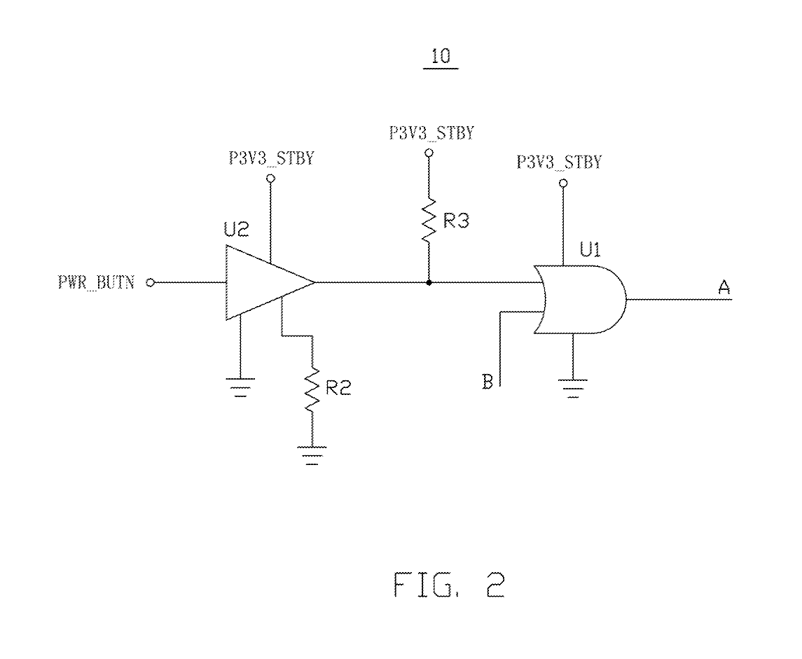

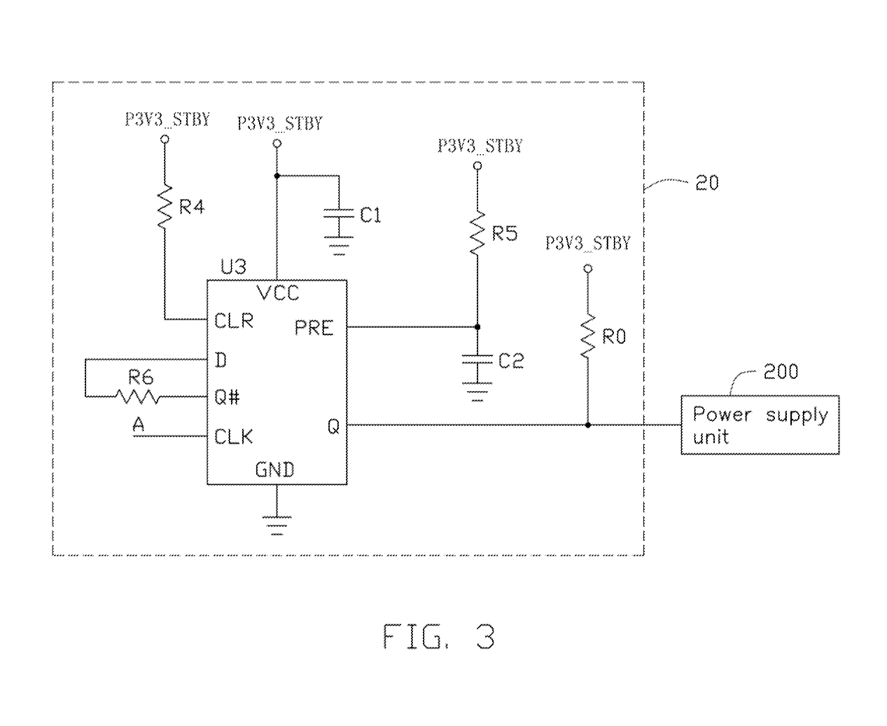

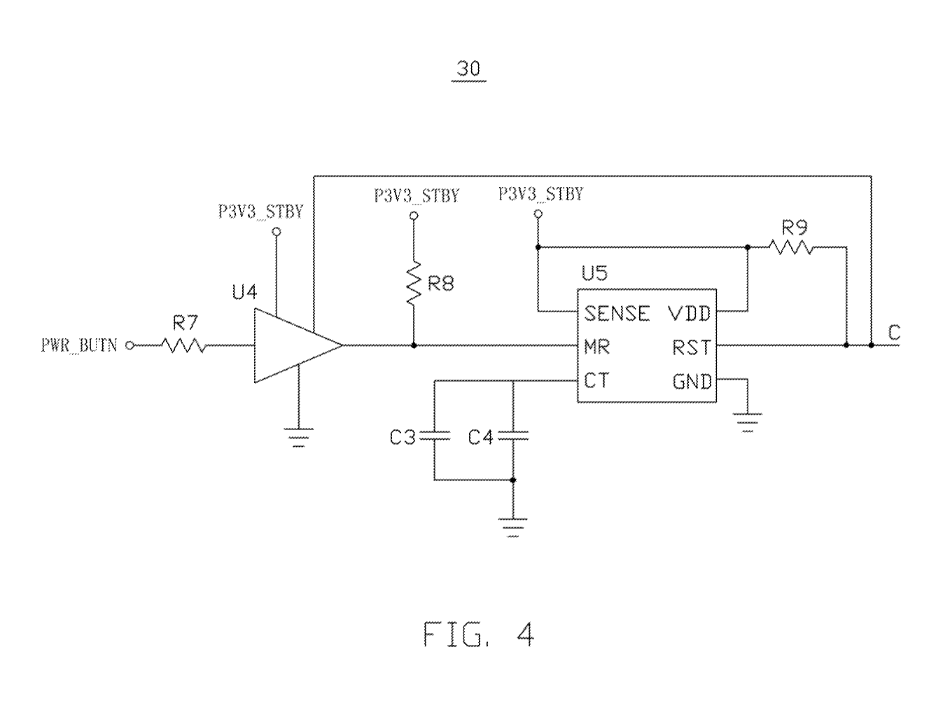

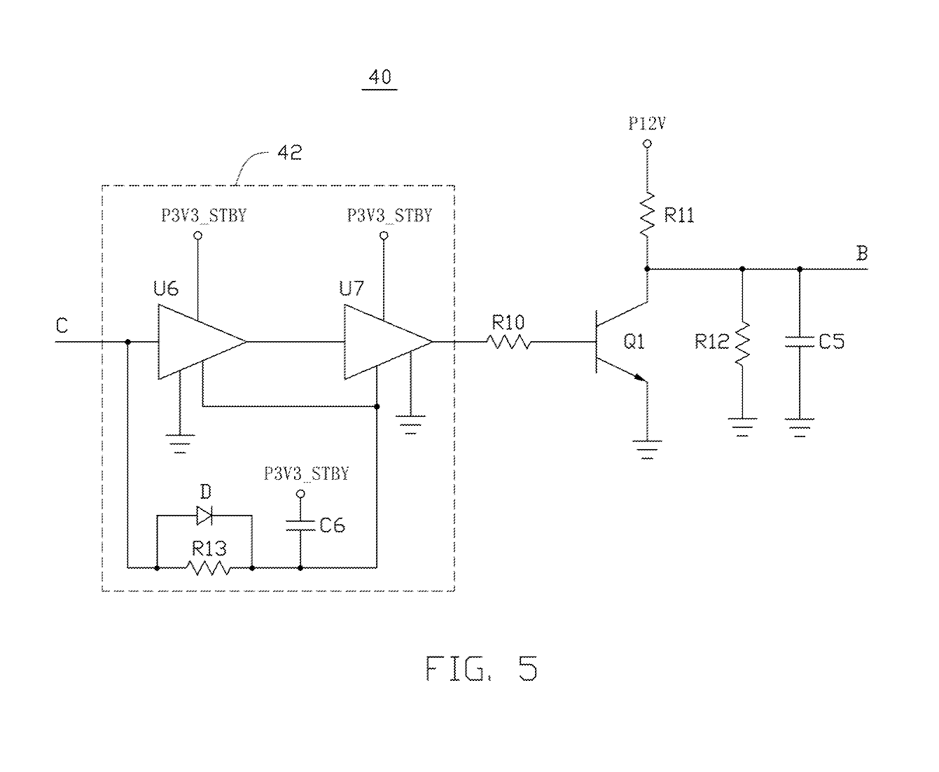

Referring to FIGS. 2-5, a circuit diagram of the switch circuit 100 is presented in accordance with the embodiment of FIG. 1 which is being thus illustrated. The selection module 10 can comprise an or gate U1, a buffer U2, and resistors R2, R3. An input terminal of the buffer U2 is configured to receive the button signal PWR_BUTN. A power terminal of the buffer U2 is coupled to a standby power supply P3V3_STBY. A ground terminal of the buffer U2 is grounded. An enable terminal of the buffer U2 is grounded through the resistor R2. An output terminal of the buffer U2 is coupled to a first input terminal of the or gate U1. The first input terminal of the or gate U1 is coupled to the standby power supply P3V3_STBY through the resistor R3. A second input terminal of the or gate U1 is coupled to the control module 40. A power terminal of the or gate U1 is coupled to the standby power supply P3V3_STBY. A ground terminal of the or gate U1 is grounded. An output terminal of the or gate U1 is coupled to the trigger module 20.

The trigger module 20 can comprise a trigger U3, capacitors C1, C2, and resistors R0, R4-R6. A power pin VCC of the trigger U3 is coupled to the standby power supply P3V3_STBY. The power pin VCC of the trigger U3 is also grounded through the capacitor C1. A clear pin CLR of the trigger U3 is coupled to the standby power supply P3V3_STBY through the resistor R4. A reset pin PRE of the trigger U3 is coupled to the standby power supply P3V3_STBY through the resistor R5. The reset pin PRE of the trigger U3 is also grounded through the capacitor C2. A clock pin CLK of the trigger U3 is coupled to the output terminal of the or gate U1. A ground pin GND of the trigger U3 is grounded. An input pin D of the trigger U3 is coupled to a first output pin Q# of the trigger U3 through the resistor R6. A second output pin Q of the trigger U3 is coupled to the power supply unit 200. The second output pin Q of the trigger U3 is coupled to the standby power supply P3V3_STBY through the resistor RO. In at least one embodiment, the trigger U3 is a delay trigger.

The delay module 30 can comprise a buffer U4, a delay chip U5, capacitors C3, C4, and resistors R7-R9. An input terminal of the buffer U4 is configured to receive the button signal PWR BUTN through the resistor R7. A power terminal of the buffer U4 is coupled to the standby power supply P3V3_STBY. A ground terminal of the buffer U4 is grounded. An output terminal of the buffer U4 is coupled to the standby power supply P3V3_STBY through the resistor R8. An input pin MR of the delay chip U5 is coupled to the output terminal of the buffer U4. A sense pin SENSE and a power pin VDD of the delay chip U5 are coupled to the standby power supply P3V3_STBY. A ground pin GND of the delay chip U5 is grounded. A delay pin CT of the delay chip U5 is grounded through the capacitor C3 and the capacitor C4 in parallel. An output pin RST of the delay chip U5 is coupled to an enable terminal of the buffer U4. The output pin RST of the delay chip U5 is coupled to the standby power supply P3V3_STBY through the resistor R9. The output pin RST of the delay chip U5 is coupled to the control module 40.

The control module 40 can comprise an isolation unit 42, an electronic switch Q1, a capacitor C5, and resistors R10-R12. In at least one embodiment, the electronic switch Q1 is an npn bipolar junction transistor (BJT). A control terminal of the electronic switch Q1 is coupled to the output pin RST of the delay chip U5 through the resistor R10 and the isolation unit 42. A first terminal of the electronic switch Q1 is coupled to a system power supply P12V through the resistor R11. A second terminal of the electronic switch Q1 is grounded. The first terminal of the electronic switch Q1 is grounded through the resistor R13 and the capacitor C5 in parallel. The second terminal of the electronic switch Q1 is coupled to the second input terminal of the or gate U1.

The isolation unit 42 can comprise buffers U6, U7, a diode D, a resistor R13, and a capacitor C6. An input terminal of the buffer U6 is coupled to the output pin RST of the delay chip U5. A power terminal of the buffer U6 is coupled to the standby power supply P3V3_STBY. A ground terminal of the buffer U6 is grounded. An output terminal of the buffer U6 is coupled to an input terminal of the buffer U7. A power terminal of the buffer U7 is coupled to the standby power supply P3V3_STBY. A ground terminal of the buffer U7 is grounded. An output terminal of the buffer U7 is coupled to the control terminal of the electronic switch Q1 through the resistor R10. An enable terminal of the buffer U6 and an enable terminal of the buffer U7 are coupled to the output pin RST of the delay chip U5 through the resistor R13. An anode of the diode D is coupled to the output pin RST of the delay chip U5 and a cathode of the diode D is coupled to the enable terminal of the buffer U7. The enable terminal of the buffer U7 is coupled to the standby power supply P3V3_STBY through the capacitor C6.

When a boot button of the JBOD 2 is pressed transitorily, the button signal PWR_BUTN is at an instantaneous low level, such as logic 0. The first input terminal of the or gate U1 receives the button signal PWR_BUTN through the buffer U2. The second input terminal of the or gate U1 receives a low level signal cause the system power supply P12V does not operate. The selection signal outputted from the output terminal of the or gate U1 is at a low level, and the clock pin CLK of the trigger U3 receives the selection signal. The trigger signal outputted from the second output pin Q of the trigger U3 changes from high level to low level. The power supply unit 200 receives the trigger signal and supplies power for the JBOD 2. The JBOD 2 boots.

When the boot button of the JBOD 2 is pressed after the preset time, the button signal PWR BUTN is at a duration low level. The first input terminal of the or gate U1 receives the button signal PWR_BUTN through the buffer U2. The control signal received by the second input terminal of the or gate U1 is at low level signal cause the delay chip U5. The selection signal outputted from the output terminal of the or gate U1 is at a low level, and the clock pin CLK of the trigger U3 receives the selection signal. The trigger signal outputted from the second output pin Q of the trigger U3 changes from low level to high level earlier than other control signals, received by the second input terminal of the or gate U1, which can control the JBOD 2 to shut down by mistake. The power supply unit 200 receives the trigger signal and stops supplying power for the JBOD 2. The JBOD 2 powers off.

The embodiment shown and described above is only example. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A switch circuit comprising:
a selection module configured to receive a button signal from a boot button;
a trigger module coupled to the selection module and configured to receive a selection signal outputted from the selection module and output a power on trigger signal and configured to output a power off trigger signal to a power supply unit according to the selection signal;
a delay module coupled to the selection module and configured to receive the button signal and output a delay signal after a preset time; and
a control module coupled between the delay module and the selection module, the control module configured to receive the delay signal and output a control signal to the selection module;
wherein the selection module is configured to output the selection signal in accordance with the received button signal and the received control signal.

2. The switch circuit of claim 1, wherein the selection module comprises an or gate, a first input terminal of the or gate is configured to receive the button signal, a second input terminal of the or gate is coupled to the control module for receiving the control signal, an output terminal of the or gate is coupled to the trigger module for outputting the selection signal, and a power terminal of the or gate is coupled to a standby power supply.

3. The switch circuit of claim 2, wherein the trigger module comprises a trigger, a first resistor, and a second resistor, a clock pin of the trigger is coupled to the output terminal of the or gate, an input pin of the trigger is coupled to a first output pin of the trigger through the first resistor, a second output pin of the trigger is coupled to the standby power supply through the second resistor, and the second output pin of the trigger is configured to output the power on trigger signal or the power off trigger signal.

4. The switch circuit of claim 3, wherein the delay module comprises a first buffer, a delay chip, a first capacitor, a third resistor, and a fourth resistor, an input terminal of the first buffer is configured to receive the button signal, an output terminal of the first buffer is coupled to the standby power supply through the third resistor, an input pin of the delay chip is coupled to the output terminal of the first buffer, a delay pin of the delay chip is grounded through the first capacitor, an output pin of the delay chip is coupled to an enable terminal of the first buffer, the output pin of the delay chip is also coupled to the standby power supply through the fourth resistor, and the output pin of the delay chip is coupled to the control module.

5. The switch circuit of claim 4, wherein the control module comprise a isolation unit, an electronic switch, and a fifth resistor, a control terminal of the electronic switch is coupled to the output pin of the delay chip through the isolation unit, a first terminal of the electronic switch is coupled to a system power supply through the fifth resistor, a second terminal of the electronic switch is grounded, and the first terminal of the electronic switch is coupled to the second input terminal of the or gate.

6. The switch circuit of claim 5, wherein the electronic switch is an npn bipolar junction transistor (BJT), and the control terminal, the first terminal, and the second terminal of the electronic switch are a base, a collector, and an emitter of the BJT, respectively.

7. The switch circuit of claim 5, wherein the isolation unit comprise a second buffer, a sixth resistor, and a second capacitor, an input terminal of the second buffer is coupled to the output pin of the delay chip, an output terminal of the second buffer is coupled to the control terminal of the electronic switch, an enable terminal of the second buffer is coupled to the output pin of the delay chip through the sixth resistor, and the enable terminal of the second buffer is coupled to the standby power supply through the second capacitor.

8. A just a bunch of disks (JBOD) comprising:
a power supply unit; and
a switch circuit comprising:
a selection module coupled to a boot button of the JBOD and configured to receive a button signal from the boot button ;
a trigger module coupled between the selection module and the power supply unit, the trigger module is configured to receive a selection signal from the selection module and output a power on trigger signal or a power off trigger signal to the power supply unit according to the selection signal;
a delay module coupled to the boot button of the JBOD configured to receive the button signal and output a delay signal after a preset time; and
a control module coupled between the delay module and the selection module, the control module configured to receive the delay signal and output a control signal to the selection module;
wherein the selection module is configured to output the selection signal in accordance with the received button signal and the received control signal.

9. The JBOD of claim 8, wherein the selection module comprises an or gate, a first input terminal of the or gate is configured to receive the button signal, a second input terminal of the or gate is coupled to the control module for receiving the control signal, an output terminal of the or gate is coupled to the trigger module for outputting the selection signal, and a power terminal of the or gate is coupled to a standby power supply.

10. The JBOD of claim 9, wherein the trigger module comprises a trigger, a first resistor, and a second resistor, a clock pin of the trigger is coupled to the output terminal of the or gate, an input pin of the trigger is coupled to a first output pin of the trigger through the first resistor, a second output pin of the trigger is coupled to the standby power supply through the second resistor, and the second output pin of the trigger is coupled to the power supply unit.

11. The JBOD of claim 10, wherein the delay module comprises a first buffer, a delay chip, a first capacitor, a third resistor, and a fourth resistor, an input terminal of the first buffer is configured to receive the button signal, an output terminal of the first buffer is coupled to the standby power supply through the third resistor, an input pin of the delay chip is coupled to the output terminal of the first buffer, a delay pin of the delay chip is grounded through the first capacitor, an output pin of the delay chip is coupled to an enable terminal of the first buffer, the output pin of the delay chip is also coupled to the standby power supply through the fourth resistor, and the output pin of the delay chip is coupled to the control module.

12. The JBOD of claim 11, wherein the control module comprise a isolation unit, an electronic switch, and a fifth resistor, a control terminal of the electronic switch is coupled to the output pin of the delay chip through the isolation unit, a first terminal of the electronic switch is coupled to a system power supply through the fifth resistor, a second terminal of the electronic switch is grounded, and the first terminal of the electronic switch is coupled to the second input terminal of the or gate.

13. The JBOD of claim 12, wherein the electronic switch is an npn BJT, and the control terminal, the first terminal, and the second terminal of the electronic switch are a base, a collector, and an emitter of the BJT, respectively.

14. The JBOD of claim 12, wherein the isolation unit comprise a second buffer, a sixth resistor, and a second capacitor, an input terminal of the second buffer is coupled to the output pin of the delay chip, an output terminal of the second buffer is coupled to the control terminal of the electronic switch, an enable terminal of the second buffer is coupled to the output pin of the delay chip through the sixth resistor, and the enable terminal of the second buffer is coupled to the standby power supply through the second capacitor.
